(19) United States
(12) Patent Application Publication
(10) Pub. No.: US 2016/0293446 A1
(43) Pub. Date: Oct. 6, 2016

(54) METHOD FOR MANUFACTURING A SILICON WAFER

(71) Applicant: GlobalWafers Japan Co., Ltd., Kitakanbara-gun (JP)

(72) Inventors: Haruo SUDO, Kitakanbara-gun (JP); Koji ARAKI, Kitakanbara-gun (JP); Tatsuhiko AOKI, Kitakanbara-gun (JP); Susumu MAEDA, Kitakanbara-gun (JP)

(73) Assignee: GlobalWafers Japan Co., Ltd., Kitakanbara-gun (JP)

(21) Appl. No.: 15/082,358

(22) Filed: Mar. 28, 2016

(30) Foreign Application Priority Data
Apr. 1, 2015 (JP) 2015-075131

(51) Int. Cl. H01L 21/324; H01L 21/311; H01L 21/02

(52) U.S. Cl. CPC H01L 21/324; H01L 21/02238; H01L 21/31111

(57) ABSTRACT

Provided is a method for manufacturing a silicon wafer including a first step of heat-treating a raw silicon wafer sliced from a silicon single crystal ingot grown by the Czochralski method in an oxidizing gas atmosphere at a maximum target temperature of 1300 to 1380° C., a second step of removing an oxide film on a surface of the heated-treated silicon wafer obtained in the first step, and a third step of heat-treating the stripped silicon wafer obtained in the second step in a non-oxidizing gas atmosphere at a maximum target temperature of 1200 to 1380° C. and at a heating rate of 1° C./sec to 150° C./sec in order that the silicon wafer may have a maximum oxygen concentration of 1.3×10¹⁸ atoms/cm³ or below in a region from the surface up to 7 μm in depth.

### BACKGROUND OF THE INVENTION

1. Field of the Invention

The present invention relates to a heat treatment of a silicon wafer sliced from a silicon single crystal ingot grown by the Czochralski method.

2. Description of the Related Art

In a silicon wafer used as a substrate for forming a semiconductor device there is a need for reducing defects, such as COP (crystal originated particles) and LSTD (laser scattering tomography defects) in a device active region on the wafer surface to ensure no defects.

Recently, as a method for preparing such a silicon wafer with high productivity, it is known that the rapid thermal process (RTP) is applied to the silicon wafer where at least a surface of the wafer for forming a semiconductor device is mirror polished.

For example, JP2001-509319A discloses a method of heat-treating a single crystal silicon wafer in an atmosphere containing oxygen at an oxygen partial pressure of less than about 5000 ppma and a temperature of more than 1175° C. for less than 60 seconds. In this method, the RTP is performed in an atmosphere mainly containing argon or helium, so that COP in the wafer surface layer can be significantly reduced.

However, in the RTP performed in an atmosphere mainly containing such an inert gas, an oxygen concentration in the surface layer of the wafer is reduced because of the out-diffusion of oxygen from the wafer surface, and consequently a pinning effect of oxygen is reduced in the heat treatment in the subsequent semiconductor device-forming step. A further problem is that the higher the heat-treatment temperature is, the more the slip dislocation occurs.

In relation to such problems, JP2010-129918A, for example, discloses that the semiconductor, which is produced by heat-treating a semiconductor wafer in a furnace atmosphere of an oxidizing gas at a temperature of 1000° C. to the melting point, allowing in-diffusion of oxygen into the part of the surface layer to introduce oxygen, withdrawing the wafer from the furnace, and cooling it, can acquire the high solid-solubility of oxygen in its surface layer, and consequently the surface layer would become a high oxygen concentration region thereby being highly strengthened.

In the RTP in such an oxidizing atmosphere as described in JP2010-129918A, the heat treatment especially at a temperature of 1300° C. or more can dissolve the inner-wall oxide film of COP and extinguish the COP, and further can dissolve the oxygen precipitate nuclei generated at the time of growing the crystal. However, the RTP in such an oxidizing gas atmosphere causes the high oxygen concentration of the surface layer of the wafer and therefore the oxygen precipitate nuclei remains. This may generate the oxygen precipitate (BMD; bulk micro-defect) in the device active region on the wafer surface during the heat treatment in the subsequent semiconductor device-forming process.

### SUMMARY OF THE INVENTION

An object of the invention is to provide a method for manufacturing a silicon wafer which can reduce crystal defects such as COP and the oxygen precipitate nuclei in the semiconductor device-forming region, to inhibit the generation of the oxygen precipitate in the device-forming region during the heat treatment in the device-forming process, and to suppress the slip dislocation.

The present invention solves the problems in the prior art and comprises the following requirements.

A method for manufacturing the silicon wafer in accordance with the present invention includes a first step of heat-treating a raw silicon wafer sliced from a silicon single crystal ingot grown by the Czochralski method (hereinafter referred to as “CZ method”) in an oxidizing gas atmosphere at a maximum target temperature of 1300 to 1380° C., a second step of removing an oxide film on a surface of the heat-treated silicon wafer obtained in the first step, and a third step of heat-treating the stripped silicon wafer obtained in the second step in a non-oxidizing gas atmosphere at a maximum target temperature of 1200 to 1380° C. and at a heating rate of 1° C./sec to 150° C./sec in order that the silicon wafer may have a maximum oxygen concentration of 1.3×10¹⁸ atoms/cm³ or below in a region from the surface up to 7 μm in depth.

A method for manufacturing the silicon wafer in accordance with the present invention makes it possible to extinguish COP and the oxygen precipitate nuclei generated during the growth of a silicon single crystal ingot effectively. Accordingly, the method of the present invention can provide a silicon wafer with thoroughly reduced crystal defects such as COP and the oxygen precipitate nuclei by the combined steps of heating a raw silicon wafer having a certain oxygen concentration in an oxidizing gas atmosphere under a specific condition, removing an oxide film, and performing the heat treatment in a non-oxidizing gas atmosphere under a certain condition. Such a silicon wafer doesn't generate the oxygen precipitate in the device-forming region and can suppress the slip dislocation during heat treatment in the device forming-process, and therefore can provide a semiconductor device with excellent strength.

### BRIEF EXPLANATION OF THE DRAWINGS

FIG. 1 is a flow chart showing a method for manufacturing the silicon wafer in accordance with the present invention.

FIG. 2 is a graph showing the oxygen concentration from a wafer surface to the depth direction.

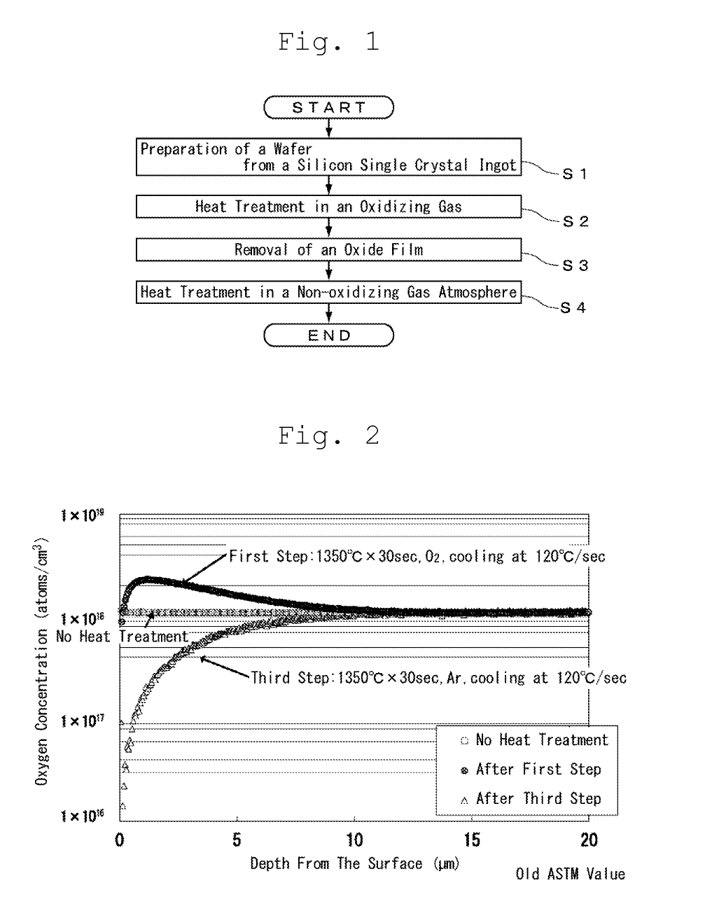

### DESCRIPTION OF THE EMBODIMENTS

A method for manufacturing the silicon wafer in accordance with the present invention includes a first step of heat-treating a raw silicon wafer sliced from a silicon single crystal ingot grown by the Czochralski method in an oxidizing gas atmosphere at a maximum target temperature of 1300 to 1380° C. (Steps S1 and S2), a second step of removing an oxide film on a surface of the heat-treated silicon wafer obtained in the first step (Step S3), and a third step of heat-treating the stripped silicon wafer obtained in the second step in a non-oxidizing gas atmosphere at a maximum target temperature of 1200 to 1380° C. and at a heating rate of 1° C./sec to 150° C./sec (Step S4) in order that the silicon wafer may have a maximum oxygen concentration of 1.3×10¹⁸ atoms/cm³ or below in a region from the surface up to 7 μm in depth.

The above-mentioned requirements are hereinafter described in detail. In the description, the silicon wafer may be abbreviated to the “wafer”.

The first step is that of heat-treating a raw silicon wafer sliced from a silicon single crystal ingot grown by the CZ method in an oxidizing gas atmosphere at a maximum target temperature of 1300 to 1380° C. (Steps S1 and S2).

The CZ method is that of filling a quartz crucible with a polycrystalline silicon, heating and fusing it by a heater, dipping a small piece of single crystal from which the crystal is to be grown, as a seed crystal in the upper surface of the silicon molten liquid, and withdrawing a rod-like crystal having a large diameter while rotating the quartz crucible and the seed crystal. As the silicon single crystal is prepared by the CZ method, oxygen atoms contained in the quartz crucible accumulate in the crystal at a high temperature. Accordingly, the CZ method can provide a raw silicon wafer containing oxygen with a desired concentration by controlling the temperature of the crucible, the number of rotation of the quartz crucible and seed crystal, or the like. The raw silicon wafer used in the present invention has normally an oxygen concentration of 0.8×10¹⁸-1.5×10¹⁸ atoms/cm³, preferably 0.9×10¹⁸-1.3×10¹⁸ atoms/cm³. When the oxygen concentration in the raw silicon wafer is in the above range, crystal defects in the silicon wafer is effectively reduced in the third step described later, and the silicon wafer with excellent strength can be obtained. The oxygen concentration is calculated in terms of the old-ASTM standard.

The raw silicon wafer thus obtained is subjected to the heat treatment in an oxidizing gas atmosphere at a maximum target temperature of 1300 to 1380° C. When the heat treatment is performed at the maximum target temperature in the above range, void defects such as COP, and the oxygen precipitate nuclei of non-uniform density generated during the growth of the silicon single crystal ingot can effectively disappear. Herein, the oxygen precipitate nuclei is considered as a complex of oxygen and a void, and grows up to be oxygen precipitate formed of silicon dioxide (SiO₂) depending on the heat treatment condition. When the maximum target temperature is less than 1300° C., the inner-wall oxide film of COP is less dissolvable because the saturating concentration of oxygen in the silicon wafer is low, and disappearance of COP may be insufficient because of low generation of interstitial silicon, and further disappearance of the oxygen precipitate nuclei may be insufficient. When the maximum target temperature is more than 1380° C., the slip dislocation tends to occur easily, and the problem of for example, generating peculiar defects on the wafer surface may occur.

The mechanism of extinguishing COP and the oxygen precipitate nuclei is described herein. Upon the heat treatment, the inner-wall oxide film of COP, namely the silicon dioxide (SiO₂) film dissolves, and a vacancy diffuses into a raw silicon wafer, thereby drawing a lot of interstitial silicon present in the wafer into this vacancies to extinguish the vacancies. However, owing to the heat treatment in an oxidizing gas atmosphere, the oxygen concentration in the sub-surface layer of the wafer (about 1 μm in depth from the surface) becomes nearly saturated during the heat treatment. For this reason, the inner-wall oxide film of COP is less dissolvable and COP tends to remain. The oxygen precipitate nuclei dissolves in the wafer and then disappears due to the heat treatment.

The heating temperature during heat treatment in the first step is normally 10 to 150° C./sec, preferably 25 to 75° C./sec. The heating rate is appropriately determined depending on the maximum target temperature. Accordingly, the nearer the maximum target temperature approaches 1300° C., the lower the heating rate, and the nearer the maximum target temperature approaches 1380° C., the higher the heating rate. When the heating rate is less than 10° C./sec, the degree of supersaturation of interstitial silicons is lowered due to reduction of the oxidation rate, and therefore COP may not disappear thoroughly. When the heating rate is more than 150° C./sec, the slip dislocation may occur easily.

The oxidizing gas can include, without limitation, any known gases capable of oxidization, but oxygen is normally used. The oxidizing gas may be a mixed gas comprising oxygen and inert gas. The partial pressure of oxygen gas is normally 20% or more and less than 100%. When the partial pressure of oxygen gas is less than 20%, the degree of supersaturation of interstitial silicons is lowered due to reduction of the oxidation rate, and therefore COP may not disappear thoroughly.

The flow rate of the oxidizing gas is normally 20 slm or more (standard liter per minute). When the flow rate of the oxidizing gas is less than 20 slm, the efficiency of air exhaustion or exchange in the chamber may be deteriorated, resulting in the contamination by impurities.

The raw silicon wafer is heated to a maximum target temperature of 1300 to 1380° C. by the heat treatment, and held for normally 5 to 60 seconds, preferably 10 to 30 seconds. When the holding time at the maximum target temperature is in the above range, COP and the oxygen precipitate nuclei generated during the growth of a silicon single crystal ingot can be reduced.

After holding a maximum target temperature of 1300 to 1380° C. for a certain time, the silicon wafer is cooled. The cooling rate at this stage is normally 150 to 25° C./sec, preferably 120 to 50° C./sec.

As described above, COP and the oxygen precipitate nuclei generated during the growth of the silicon single crystal ingot in the first step can effectively disappear.

The second step includes removing an oxide film formed on both the front and rear sides (including the edge side) of the heat-treated silicon wafer obtained in the first step (Step S3). If the oxide film is not removed, it is difficult to lower the oxygen concentration in the surface layer of the wafer in the following third step.

The heat-treated silicon wafer, whose front and rear surfaces are oxidized, is covered with an oxide film of silicon dioxide (SiO₂). The thickness of the oxide film is approximately 5 to 30 nm, depending on the partial pressure and the flow time of the oxidizing gas.

The oxide film formed on the front and rear surfaces of the heat-treated silicon wafer is dissolved and removed by dipping the wafer in a dilute acid. The dilute acid includes, but without limitation, various kinds of acids as long as it can dissolve an oxide film. For example, hydrofluoric acid (HF(aq)) can be used.

The third step is that of heat-treating the stripped silicon wafer obtained in the second step in a non-oxidizing gas atmosphere at a maximum target temperature of 1200 to 1380° C. and at a heating rate of 1 to 150° C./sec (Step S4). Through the third step, it is possible to reduce the increased oxygen concentration in the surface part of the wafer due to the heat treatment in the oxidizing atmosphere during the first step, and also is possible to extinguish COP remaining in the sub-surface layer.

In the third step, when the maximum target temperature is less than 1200° C., it takes time to reduce the oxygen concentration in the surface part of the silicon wafer due to the slow diffusion rate of oxygen, and therefore the final productivity of the silicon wafer may be lowered. When the maximum target temperature is more than 1380° C., peculiar defects by Si sublimation may be generated on the front and rear surfaces of the wafer.

The heating rate in the third step is 1 to 150° C./sec, preferably 10 to 90° C./sec, more preferably 25 to 75° C./sec. When the heating rate is less than 1° C./sec, namely the heating rate is too low, the oxygen precipitate may be gradually generated in the surface part of the wafer with heating during the third step. When the heating rate is more than 150° C./sec, the slip dislocation may possibly occur in the wafer.

The wafer is heated to a maximum target temperature of 1200 to 1380° C. at a heating rate of 1 to 150° C./sec, and then is held for normally 1 to 60 seconds, preferably 5 to 30 seconds to reduce the oxygen concentration of surface layer.

The non-oxidizing gas includes, but without limitation, any known gas as long as it does not oxidize the wafer. For example, argon can be used in terms of preventing the formation of a nitride film and the like, or in terms of not causing another chemical reaction.

In the third step, the oxygen concentration in the surface layer of the silicon wafer, which was increased in the first step can be lowered by the above heat treatment. Specifically, as shown in FIG. 2, the maximum value of the oxygen concentration from the surface of the silicon wafer to 7 μm in depth is controlled to 1.3×10¹⁸ atoms/cm³ or less. When the maximum value of the oxygen concentration is more than 1.3×10¹⁸ atoms/cm³, the oxygen precipitate nuclei tends to be generated, thereby maybe causing a problem that the oxygen precipitate nuclei in the surface layer grows to generate the oxygen precipitate in the semiconductor device-forming process. The oxygen concentration in the region from the surface of the silicon wafer to 7 μm in depth is determined by appropriately controlling the oxygen concentration in the raw silicon wafer, the heating rate in the third step, the maximum target temperature, and the holding time at the maximum target temperature.

After holding the maximum target temperature for a certain time, the silicon wafer needs to be cooled. By controlling this cooling step appropriately, it is possible to form the oxygen precipitate nuclei in the bulk region and to verify its density. The cooling rate is normally 150° C./sec or less, preferably 120 to 5° C./sec. On the whole, when the cooling rate is high, the density of the oxygen precipitate nuclei is high, and when the cooling rate is low, the density of the oxygen precipitate nuclei is low. When the cooling rate is less than 5° C./sec, not only lowered is the productivity but also deterioration or damage of the wafer may be caused because the time of the heat treatment after reaching the high temperature becomes very long and the members forming the apparatus are heated up. On the other hand, when the cooling rate is more than 150° C./sec, the slip dislocation may occur in the wafer.

After the third step, the silicon wafer may be purified by removing the surface of either or both sides thereof. The removing method normally includes, but without limitation, wiping either or both sides of the wafer with an abrasive cloth dipped in a slurry. The method may be used in combination with the polishing processing by using a whetstone or a lap surface plate and the chemical etching.

By purifying the wafer as just described, the coarse surface generated at the time of the high-temperature heat treatment can be removed.

### EXAMPLES

The present invention is hereinafter described in further detail with reference to Examples, but the present invention is not limited thereto.

[Method of Manufacturing a Silicon Wafer]

A silicon single crystal ingot having a vacancy-dominated region was grown by the CZ method where the ratio V/G of the withdrawal rate V to the average value G of the withdrawal axial temperature gradient in the crystal is controlled within a temperature region of from the melting point of silicon to 1300° C. The ingot was sliced and mirror polished on both sides to give a raw silicon wafer having a diameter of 300 mm.

The raw silicon wafer obtained had an oxygen concentration of 1.1×10¹⁸ atoms/cm³ and a nitrogen concentration of 2.5×10¹⁴ atoms/cm³.

### Examples 1 to 10

As the first step, a raw silicon wafer was heat-treated in an atmosphere of 100% oxygen (flow rate: 20 slm) at a heating rate of 50° C./sec, at a maximum target temperature of 1300 to 1380° C., at a holding time at the maximum target temperature of 30 seconds, and at a cooling rate of 120° C./sec. Then, as the second step, the heat-treated silicon wafer thus obtained was washed with hydrofluoric acid (dilute HF) to remove an oxide film on the surface completely. Further in the third step, the heat treatment was performed in an atmosphere of 100% argon (flow rate: 20 slm) at a heating rate of 1 to 150° C./sec, at a maximum target temperature of 1200 to 1380° C., at a holding time at the maximum target temperature of 1 to 60 seconds, and at a cooling rate of 120° C./sec so that the maximum oxygen concentration could be 1.3×10¹⁸ atoms/cm³ or less in a region from the silicon wafer surface to 7 μm in depth.

The oxygen concentration in the depth direction from the surface of the silicon wafer obtained was measured by the SIMS (secondary ion mass spectroscopy; IMS7f by CAMECA Division, AMETEK Co., Ltd.), and the maximum oxygen concentration in a region from the surface to 7 μm in depth was determined from the profile plots obtained in the depth direction.

The heat treatment was also performed in a nitrogen atmosphere at a heating rate of 5° C./min, at a maximum target temperature of 1000° C., for a holding time of 4 hours at the maximum target temperature, and at a cooling rate of 5° C./min on the assumption of the heat treatment in the semiconductor device-forming process. To evaluate the degree of generation of the oxygen precipitate in the surface part of the heat-treated wafer, after the third step, the part from the wafer surface to 7 μm in depth was removed by polishing to the point where the maximum oxygen concentration was reached. The number of LPDs (Light Point Defects) having a size of ≧40 nm was calculated by using the Surfscan SP2, manufactured by KLA-Tencor Japan Ltd. In addition, the slip length in the wafer was determined by using the X-ray topography (XRT300 manufactured by RIGAKU Corporation).

The manufacturing conditions and evaluation results of Examples 1 to 10 are shown in Table 1.

### Comparative Example 1

A silicon wafer was prepared in the same manner as Examples, except that the maximum oxygen concentration in the third step was 1.35×10¹⁸ atoms/cm³ (i.e., concentration of >1.3×10¹⁸ atoms/cm³) .

### Comparative Example 2

A silicon wafer was prepared in the same manner as Examples, except that the maximum temperature of the heat treatment in the third step was 1175° C., and the maximum value of the oxygen concentration in a region from the silicon wafer surface to 7 μm in depth was controlled to 1.50×10¹⁸ atoms/cm³ or less.

### Comparative Example 3

A silicon wafer was prepared in the same manner as Examples, except that the maximum temperature of the heat treatment in the third step was 1385° C.

### Comparative Example 4

A silicon wafer was prepared in the same manner as Examples, except that the heating rate in the third step was 0.5° C./sec.

### Comparative Example 5

A silicon wafer was prepared in the same manner as Examples, except that the heating rate in the third step was 155° C./sec.

The manufacturing conditions and evaluation results of Comparative Examples 1 to 4 are shown in Table 1.

TABLE 1

| | | | | | | The Number of LPDs at a |
|---|---|---|---|---|---|---|
| | 1^{st} step | 3^{rd} step | | | | Point of the Maximum |
| | Maximum | | Maximum | Maximum | | Oxygen concentration |
| | Target | Heating | Target | Oxygen | Slip | in the Region from the |
| | Temperature | Rate | Temperature | Concentration | Length | Surface to 7 μm in Depth |
| | (° C.) | (° C./sec) | (° C.) | (×10¹⁸/cm³) | (mm) | after the 3^{rd} Step |
| Comp. Ex. 1 | 1350 | 50 | 1300 | 1.35 | 0 | >10,000 |
| Ex. 1 | 1300 | 50 | 1300 | 1.10 | 0 | 49 |
| Ex. 2 | 1350 | 50 | 1300 | 1.30 | 0 | 54 |
| Ex. 3 | 1380 | 50 | 1300 | 1.30 | 1 | 44 |
| Ex. 4 | 1350 | 50 | 1200 | 1.30 | 0 | 30 |
| Ex. 5 | 1350 | 50 | 1350 | 0.70 | 0 | 70 |
| Ex. 6 | 1350 | 50 | 1380 | 0.50 | 1 | 122 |
| Comp. Ex. 2 | 1350 | 50 | 1175 | 1.50 | 0 | >10,000 |
| Comp. Ex. 3 | 1350 | 50 | 1385 | 0.40 | 1 | 2,017 |
| Ex. 7 | 1350 | 1 | 1300 | 1.20 | 0 | 105 |
| Ex. 8 | 1350 | 10 | 1300 | 1.30 | 0 | 70 |
| Ex. 9 | 1350 | 100 | 1300 | 1.30 | 0 | 34 |
| Ex. 10 | 1350 | 150 | 1300 | 1.30 | 2 | 29 |
| Comp. Ex. 4 | 1350 | 0.5 | 1300 | 1.10 | 0 | >10,000 |
| Comp. Ex. 5 | 1350 | 155 | 1300 | 1.30 | 10 | 47 |

After the heat treatment with an assumption of the semiconductor device-forming process and the abrasion and removal of the wafer surface layer of 5 μm, in the evaluation of LPDs having a size of ≧40 nm, it is confirmed that the generation amount of the oxygen precipitate in Examples 1 to 10 and Comparative Example 5 is no problem for the device forming process. On the other hand, the number of LPDs in Comparative Examples 1, 2, and 4 is more than 10,000, and it is confirmed that the generation of the oxygen precipitate nuclei cannot be inhibited. In Comparative Example 2, when the maximum temperature of the heat treatment was set at 1175° C. in the third step, and the heat treatment was performed so that the maximum oxygen concentration in a range from the silicon wafer surface to 7 μm in depth could be 1.3×10¹⁸ atoms/cm³ or less, it is confirmed that the final production efficiency of the silicon wafer is lowered because it took time to reduce the oxygen concentration of the surface layer of the silicon wafer. The number of LPDs in Comparative Example 3 is 2,017, indicating that the peculiar defects were generated due to the heat temperature at high temperature.

After the heat treatment on an assumption of the semiconductor device-forming process, in the slip evaluation generated in the wafer of Examples 1 to 10, few slip dislocations were observed. In Comparative Example 5, the number of LPDs was small, but the slip dislocation was observed.

As described above, according to the present invention, it turns out that the silicon wafer with thoroughly reduced crystal defects such as COP and the oxygen precipitate nuclei in the device-forming region is obtained by performing the heat treatment including the first and third steps for a raw silicon wafer having a certain oxygen concentration under a certain condition.

What is claimed is:

1. A method for manufacturing a silicon wafer including a first step of heat-treating a raw silicon wafer sliced from a silicon single crystal ingot grown by the Czochralski method in an oxidizing gas atmosphere at a maximum target temperature of 1300 to 1380° C., a second step of removing an oxide film on a surface of the heated-treated silicon wafer obtained in the first step, and a third step of heat-treating the stripped silicon wafer obtained in the second step in a non-oxidizing gas atmosphere at a maximum target temperature of 1200 to 1380° C. and at a heating rate of 1° C./sec to 150° C./sec in order that the silicon wafer may have a maximum oxygen concentration of 1.3×10¹⁸ atoms/cm³ or below in a region from the surface up to 7 μm in depth.
